(19) United States
(12) Patent Application Publication
(10) Pub. No.: US 2006/0243422 A1
(43) Pub. Date: Nov. 2, 2006

(54) Liquid-cooled semiconductor unit for cooling high-power semiconductor elements that are enclosed in modules

(75) Inventors: Yasuyuki Sakai, Oobu-shi (JP); Yukitoshi Narumi, Kariya-shi (JP); Hirofumi Kako, Aichi-ken (JP)

Correspondence Address: NIXON & VANDERHYE, PC, 901 NORTH GLEBE ROAD, 11TH FLOOR, ARLINGTON, VA, 22203, US

(73) Assignee: Denso Corporation, Kariya-city (JP)

(21) Appl. No.: 11/411,949

(22) Filed: Apr. 27, 2006

(30) Foreign Application Priority Data
Apr. 28, 2005 (JP) 2005-132386
Mar. 9, 2006 (JP) 2006-063768

(51) Int. Cl. H05K 7/20

(52) U.S. Cl. 165/80.4; 361/699; 165/153

(57) ABSTRACT

In a liquid-cooled semiconductor unit having one or more semiconductor modules and a plurality of cooling tubes arrayed in parallel, with each semiconductor module sandwiched between a pair of cooling tubes, a coolant supply header for supplying a flow of liquid coolant through respective flow passages in the cooling tubes and a coolant discharge header for discharging the liquid coolant from these coolant flow passages, each of the cooling tubes is disposed with an outlet end aperture portion thereof located at a higher elevation than an intake end aperture portion thereof.

### CROSS-REFERENCE TO RELATED APPLICATIONS

This application is based on and incorporates herein by reference Japanese Patent Application No. 2005-132386 filed on Apr. 28, 2005 and Japanese Patent Application No. 2006-063768 filed on Mar. 9, 2006.

### BACKGROUND OF THE INVENTION

1. Field of Application

The present invention relates to a liquid-cooled semiconductor unit having one or more semiconductor modules, each enclosing one or more semiconductor elements, and a plurality of cooling tubes through which a liquid coolant flows for cooling the semiconductor modules and thereby cooling the semiconductor elements.

2. Description of Related Art

Power conversion devices such as DC-DC converters, power inverters, etc., are used, for example, to supply drive current to an AC motor that serves as a motive power in an electric vehicle or hybrid electric type of vehicle (i.e., which can be driven by an internal combustion engine and/or AC motor). In such an application, it is generally necessary to supply a large drive current to the AC motor, to achieve a sufficiently high torque from the motor for driving the vehicle. The high-power semiconductor elements such as IGBTs (Insulated Gate Bipolar Transistors) that are used in a power conversion device which supplies the drive current to such an AC motor are generally enclosed within one or more solid modules, referred to herein as semiconductor modules. Due to the large current that must be fed by these semiconductor elements, the semiconductor modules generate large amounts of heat.

As described for example in Japanese patent publication No. 2002-26215 and shown in FIGS. 8, 9 of the present application, to achieve even cooling of a plurality of semiconductor modules 92 of a power converter apparatus, a liquid-cooled semiconductor unit 9 is utilized which has a plurality of cooling tubes 93 each connected to a coolant supply header and a coolant discharge header, with a liquid coolant flowing from the coolant supply header through the cooling tubes to the coolant discharge header, and with each of the semiconductor modules 92 being sandwiched between two of the cooling tubes 93. In FIGS. 8 and 9, numeral 90 denotes an outer case of a power converter apparatus incorporating the liquid-cooled semiconductor unit 9.

With such a type of liquid-cooled semiconductor unit, the following problems arise. The liquid-cooled semiconductor unit 9 is disposed with the cooling tubes 93 arrayed horizontally. As can be seen from FIG. 9, when boiling of the liquid coolant occurs, so that vapor bubbles By are formed, these bubbles will tend to remain within the flow paths of the liquid coolant in the cooling tubes 93. As a result, the cooling efficiency of the cooling tubes 93 may be significantly reduced.

Moreover at certain times, in particular when the liquid-cooled semiconductor unit 9 is first installed in a vehicle and liquid coolant is then introduced into a cooling system that includes the cooling tubes 93, it is necessary to bleed residual air from the interior of the liquid-cooled semiconductor unit 9. However this has proven difficult, with possible air bubbles being left within the cooling tubes 93 after the air bleeding operation has been performed.

Furthermore when the vehicle having the liquid-cooled semiconductor unit 9 is halted, after having been driven for some time, and the circulating pump which drive the liquid coolant through the liquid-cooled semiconductor unit 9 is then halted, the semiconductor modules 92 will still keep generating substantial amounts of residual heat. In that condition, since the liquid coolant is not being circulated through the cooling tubes 93, the liquid coolant within these tubes experience to an excessively high temperature, so that the cooling of the semiconductor modules may become insufficient.

### SUMMARY OF THE INVENTION

It is an objective of the present invention to overcome the above problems, by providing a liquid-cooled semiconductor unit which has a high efficiency of cooling of the semiconductor modules.

To achieve the above objectives, the invention provides a liquid-cooled semiconductor unit having a plurality of cooling tubes arrayed parallel to one another, with each of one or more semiconductor modules sandwiched between a corresponding pair of the cooling tubes, and with each of the cooling tubes containing a coolant flow passage for flowing a liquid coolant. The unit further includes a coolant supply header that is connected to respective intake end aperture portions of the cooling tubes, for supplying the liquid coolant to the coolant flow passages, and a coolant discharge header that is connected to respective outlet end aperture portions of the cooling tubes, for discharging the liquid coolant from the coolant flow passages. The liquid-cooled semiconductor unit is characterized in that each of the cooling tubes is disposed with its outlet end aperture portion located at a higher elevation than its intake end aperture portion.

As a result of thus locating the outlet end apertures of the cooling tubes at a higher elevation than the intake end apertures, if there are any bubbles of vaporized coolant within the flow passage in a cooling tube (i.e., due to boiling of the liquid coolant as a result of heat transferred from an adjacent semiconductor module), the effects of buoyancy will ensure that the bubbles will rise to the outlet end aperture of the cooling tube, and so will be carried through the coolant discharge header by the flow of liquid coolant. It can thereby be ensured that such bubbles will not remain within the flow paths in the cooling tubes. Deterioration of the efficiency of cooling of the semiconductor modules, as a result of retained bubbles, can thereby be prevented.

In addition, bleeding of air from the interior of the liquid-cooled semiconductor unit, e.g., when first installing the liquid-cooled semiconductor unit in a vehicle, can be easily and effectively performed. Specifically, when the liquid coolant is introduced into the interior of the liquid-cooled semiconductor unit at the time of installation, i.e., pouring coolant into the supply header and from there flowing upward through each of the cooling tubes to the coolant discharge header, air will be smoothly removed from the flow passages in the cooling tubes and in the coolant supply header and coolant discharge header, and replaced by the liquid coolant. The possibility of air bubbles becoming trapped within the flow paths in the liquid-cooled semiconductor unit can thereby be effectively eliminated, so that bleeding of air can be reliably achieved.

Moreover, in a case in which the vehicle having the liquid-cooled semiconductor unit becomes halted (after having been driven for some time) and the circulating pump of the liquid coolant of the liquid-cooled semiconductor unit is then halted, large amounts of residual heat will remain in the semiconductor modules. However with the present invention, natural convection currents of the liquid coolant within the cooling tubes (due to the fact that the outlet end aperture of each tube is located higher than the intake end aperture, and the heated coolant will rise due to buoyancy) will cause the coolant circulation to be continued, with the heated liquid coolant flowing from the cooling tubes into the coolant discharge header. Hence, it can be ensured that regions of liquid coolant at a very high temperature will not be formed in the cooling tubes under such a condition.

Effective dissipation of the residual heat from the semiconductor modules can thereby be ensured, by natural circulation of the liquid coolant, even after forced circulation effected by the circulating pump has been halted. Thus efficient cooling of the semiconductor modules can be maintained in such a situation.

From another aspect of the invention, a coolant discharge passage within the coolant discharge header of the liquid-cooled semiconductor unit is preferably formed with no downwardly-directed portions, i.e., portions that would result in a downward direction of flow of the liquid coolant. Specifically, the coolant discharge passage is preferably oriented horizontally, or sloping upward, or having a combination of horizontal and upwardly-sloping portions. Such a configuration serves to further prevent bubbles from remaining within flow paths in the liquid-cooled semiconductor unit, thereby enhancing the efficiency of cooling of the semiconductor modules.

That is to say, if any downward-sloping (more specifically, downward-sloping or vertically downward) portions were to be formed in the flow passage within the coolant discharge header, then bubbles of air or vaporized coolant could become trapped at the upper end of such a downward-sloping portion. However by forming the flow passage with only horizontal or upward-sloping portions (more specifically, upward-sloping or oriented vertically upward, such as to produce an upwardly directed flow of the liquid coolant), it can be ensured that all bubbles will be drawn along with the flow of the liquid coolant, and thereby extracted as the coolant flows out from the coolant discharge header.

Similarly, a coolant supply flow passage within the coolant supply header is preferably formed with no downwardly sloping portions.

In addition, the coolant supply header and coolant discharge header are preferably disposed parallel to one another, with the cooling tubes extending at right angles to the coolant supply header and to the coolant discharge header. Such a configuration enables the liquid-cooled semiconductor unit to be made of compact size.

Furthermore the cooling tubes are preferably oriented vertically. This ensures that any bubbles that form within the coolant flow passages inside the cooling tubes will be readily extracted, and so will not adversely affect the efficiency of cooling the semiconductor modules.

From another aspect of the invention, the coolant discharge header preferably contains a coolant discharge passage having a cross-sectional area that is larger than the cross-sectional area of a coolant supply flow passage within the coolant supply header. This provides the advantage that vapor bubbles which are generated within the flow paths in the cooling tubes will rise into a region of relatively cool liquid within the coolant discharge passage, and so will be rapidly condensed back to liquid form.

From a further aspect, each of the cooling tubes is preferably formed internally with a plurality of cooling fins, i.e., located within the coolant flow passage of said cooling tube. This serves to increase the effective area of contact between the cooling tubes and the liquid coolant, thereby enhancing the heat exchange efficiency of the unit.

With such a configuration, the coolant supply header is preferably formed with a plurality of pockets, each located below a corresponding one of the cooling tubes, and each extending downward from the interior of the coolant supply passage in the coolant supply header. In that way, any solid foreign material that is carried into the coolant supply passage by the flow of coolant, and so reaches the intake end of a set of cooling fins within a cooling tube and becomes large enough to clog that intake end, will subsequently fall into the corresponding pocket below the cooling tube when the flow of liquid coolant is thereafter halted. This serves to ensure that such solid foreign material will not accumulate at the intake end of a set of cooling fins, and so prevents obstruction to the flow of coolant through the cooling tubes by such solid foreign material, since the solid foreign material will be removed from the flow path within the coolant supply passage.

### BRIEF DESCRIPTION OF THE DRAWINGS

FIG. 1 is a side view of a first embodiment of a liquid-cooled semiconductor unit;

FIG. 2 is an oblique view of the first embodiment;

FIGS. 3, 4 and 5 are conceptual cross-sectional views in elevation of respective liquid-cooled semiconductor unit configurations, provided for purposes of explanation;

FIG. 6 is a conceptual cross-sectional view in elevation of a second embodiment of a liquid-cooled semiconductor unit, in which respective flow paths within a coolant supply header and a coolant discharge header are each oriented with an upward slope;

FIG. 7 is a cross-sectional view in elevation of a third embodiment of a liquid-cooled semiconductor unit, in which each of respective cooling tubes contains a set of internal cooling fins;

FIG. 8 is an oblique view of a related art example of a liquid-cooled semiconductor unit; and

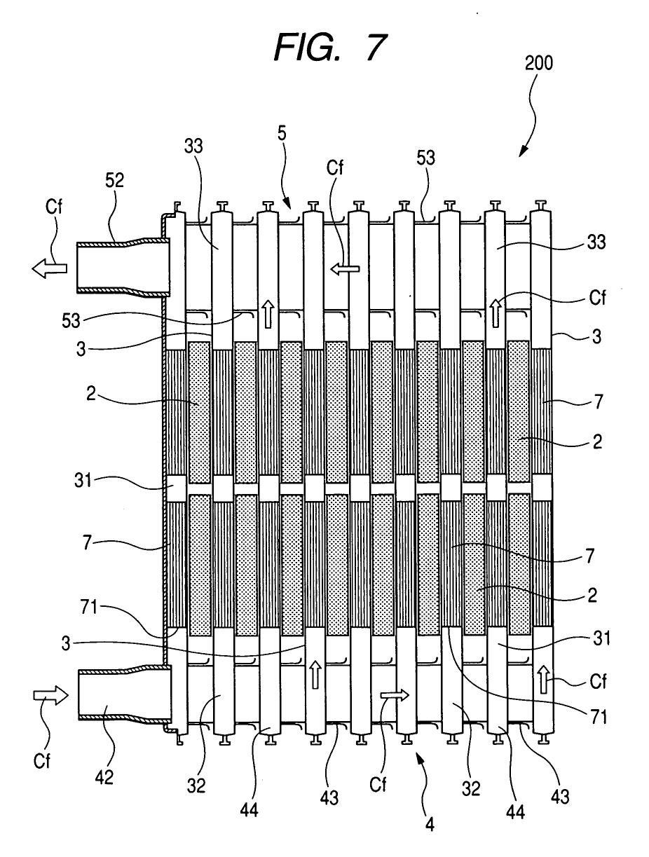

FIG. 9 is a cross-sectional view in elevation of the related art example of FIG. 8.

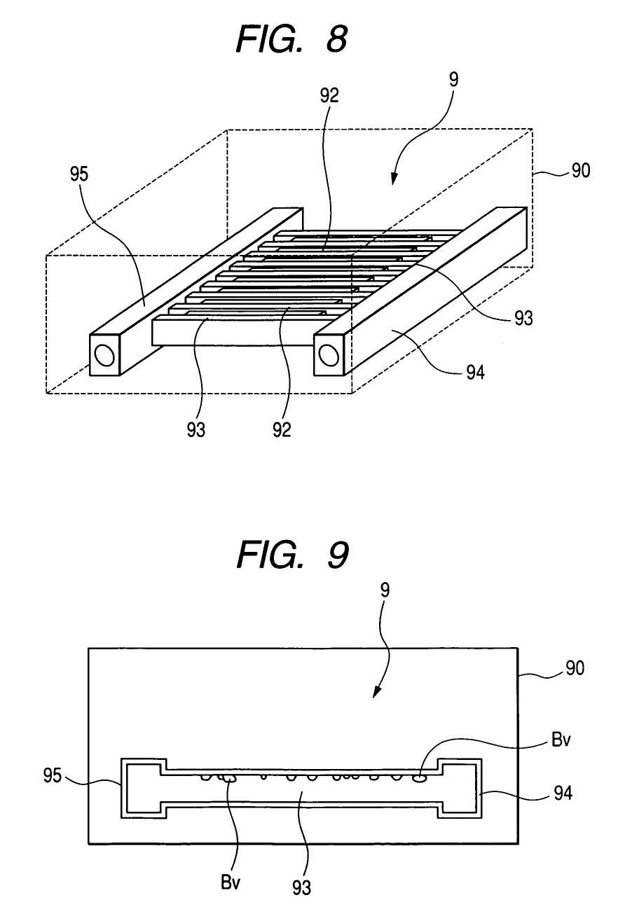

### DESCRIPTION OF PREFERRED EMBODIMENTS

### First Embodiment

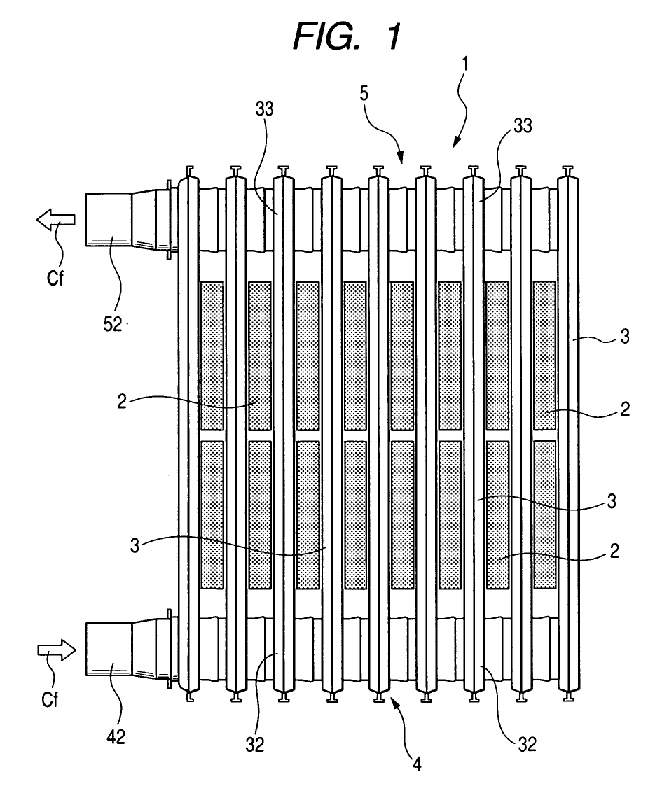

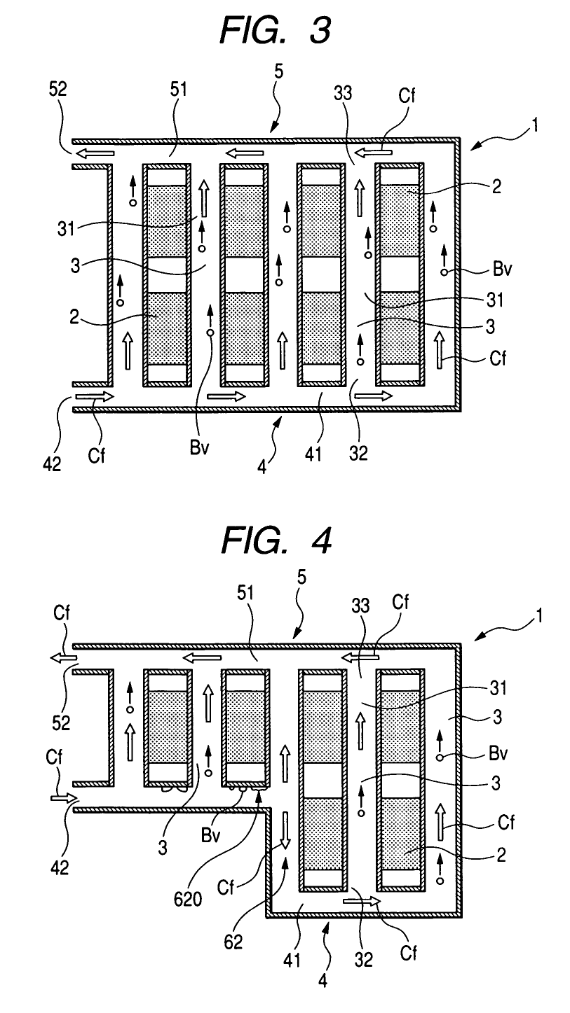

A first embodiment of a liquid-cooled semiconductor unit (referred to in the following simply as a cooled semiconductor unit) will be described referring to FIGS. 1 to 5. FIGS. 3 to 5 are simplified conceptual cross-sectional diagrams, provided for describing the advantageous effects obtained by the first embodiment.

As shown in FIGS. 1 to 3 the cooled semiconductor unit, designated by reference numeral 1, includes a plurality of semiconductor modules 2 (each having one or more semiconductor elements internally contained therein), and a plurality of cooling tubes 3 which are arrayed in parallel, with each of the semiconductor modules 2 being sandwiched between two of the cooling tubes 3 as shown.

A coolant supply header 4 of the cooled semiconductor unit 1 is connected to the respective intake end apertures 32 of the cooling tubes 3, with a coolant supply passage 41 within the coolant supply header 4 communicating with (i.e., opening into) respective coolant flow passages within the cooling tubes 3. Similarly, a coolant discharge header 5 of the cooled semiconductor unit 1 is connected to the respective outlet end apertures 33 of the cooling tubes 3, with a coolant discharge passage 51 within the coolant discharge header 5 communicating with the respective coolant flow passages in the cooling tubes 3.

As illustrated by the arrow symbols in FIG. 1, a liquid coolant designated as Cf is forced to flow into a coolant intake aperture 42 of the coolant supply header 4 by a coolant circulation pump (not shown in the drawings), with the liquid coolant Cf thereby flowing through the coolant supply passage 41 within the coolant supply header 4 to the respective coolant flow passages 31 within the cooling tubes 3, then through the coolant discharge passage 51 within the coolant discharge header 5, to exit from the cooled semiconductor unit 1 via a coolant outlet aperture 52 of the coolant discharge header 5 and hence back to the intake port of the coolant circulation pump.

It is a basic feature of the embodiment that (i.e., when the cooled semiconductor unit is in a condition of being utilized, such as when mounted in a vehicle) the outlet end aperture of each of the cooling tubes 3 is disposed at a position higher than the intake end aperture of the cooling tube.

Such a cooled semiconductor unit can advantageously be utilized in a power converter apparatus such as a DC-DC converter or power inverter for producing the drive current of an AC motor that serves as the motive power for an electric vehicle or hybrid electric vehicle.

The semiconductor elements within each semiconductor module can for example be IGBTs, MOS FETs (Metal-Oxide Semiconductor Field Effect Transistors) or other types of transistors, diodes, thyristors, power integrated circuits, etc.

The liquid coolant can for example be water mixed with an antifreeze substance such as ethylene glycol, or a natural coolant such as water or ammonia, or a fluorocarbon type of coolant such as florinate, or a freon type of coolant such as HCFC123, HFC134a, etc., or an alcohol type of coolant such as ethanol, or a ketone type of coolant such as acetone, etc.

As shown in FIGS. 1 to 3, the coolant supply header 4 and the coolant discharge header 5 are aligned parallel to one another, with each of the cooling tubes 3 being aligned at right angles to the coolant supply header 4 and to the coolant discharge header 5. In addition, with this embodiment, each of the cooling tubes 3 is oriented vertically, while each of the coolant supply header 4 and the coolant discharge header 5 is oriented horizontally, with no part of the coolant flow passages within the coolant supply header 4 and coolant discharge header 5 being formed with a downward slope. The term “downward slope” or “downwardly directed” applied to a portion of a coolant flow passage, as used herein, signifies that the portion has an orientation that will result in a (sloping or vertical) downward direction of flow.

As a result of this configuration, the coolant outlet aperture 52 located at one end of the coolant discharge header 5, is at a higher elevation than the coolant intake aperture 42, which is located at one end of the coolant supply header 4.

With this embodiment, two semiconductor modules 2 are disposed at successive locations along the vertical direction, sandwiched between (i.e., enclosed between and in contact with) an adjacent pair of the cooling tubes 3. It should be noted that in addition to containing semiconductor elements such as IGBTs, etc., it would be possible for each semiconductor module 2 (or one or more of the semiconductor modules 2) to contain a temperature sensor, which could be used to generate a temperature signal for monitoring the temperature of a semiconductor module 2.

The temperature of each semiconductor module 2 tends to become the highest at the downstream end of the module and in particular the upper ends of the semiconductor modules 2 that are located adjacent to the coolant discharge header 5 will tend to become the highest in temperature. Each of the semiconductor modules 2 is held in direct contact with adjacent cooling tubes 3, thereby to be cooled by the flow of the liquid coolant Cf through the flow passages in these cooling tubes 3, i.e., by heat exchange between each semiconductor module 2 and the coolant flowing in the adjacent cooling tubes 3.

As conceptually illustrated in FIG. 3, the heated liquid coolant Cf rises due to buoyancy within the coolant flow passages 31 in the cooling tubes 3, to reach the coolant discharge header 5, and then flows out from the coolant discharge header 5 via the coolant outlet aperture 52.

In that way, even when forced circulation of the liquid coolant Cf by a circulation pump is halted, circulation of the coolant will naturally occur, thereby effecting cooling of the semiconductor modules 2.

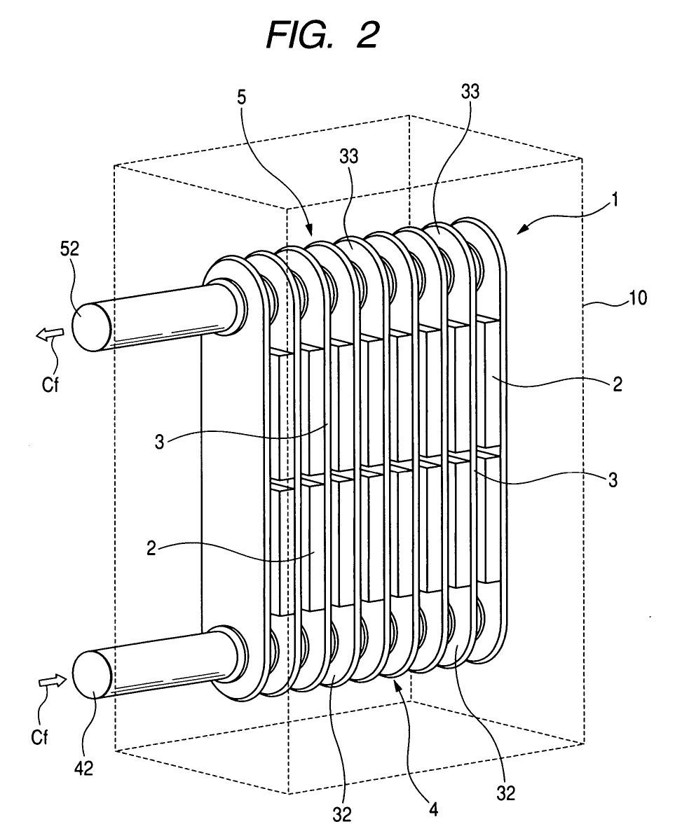

The external configuration of this embodiment is illustrated in the oblique view of FIG. 2, in which numeral 10 denotes an external housing of a power converter apparatus which incorporates the cooled semiconductor unit 1.

The following effects are obtained with this embodiment. The outlet end aperture portions 33 of the cooling tubes 3 are each located at a higher location than the intake end aperture portions 32, so that as shown in FIG. 3, even if bubbles By of coolant vapor become mixed within the liquid coolant in the cooling tubes 3, the bubbles will rise due to buoyancy, up to the outlet end aperture portions 33, and so will then exit through the coolant discharge header 5. As a result, it can be ensured that such bubbles By will not remain within the coolant flow passages 32 in the cooling tubes 3, so that deterioration of the cooling efficiency due to the presence of such bubbles can be prevented.

Moreover, bleeding of air from the cooled semiconductor unit 1 at the time of installation in a vehicle can be readily and effectively performed. That is to say, when liquid coolant begins to be introduced via the coolant intake aperture 42 into the interior of the cooled semiconductor unit 1, it can be understood that the air within the interior of the cooled semiconductor unit 1 will be efficiently extracted, through the intake end aperture portions 32 of the cooling tubes 3 and then via the coolant outlet aperture 52.

Furthermore when the operation of the circulation pump that drives the liquid coolant through the cooled semiconductor unit 1 is halted, with the semiconductor modules 2 being left in a hot condition, it will be ensured that there will be no residual regions of high-temperature liquid coolant within the coolant flow passages 31 of the cooling tubes 3. In such a condition, regions of the liquid coolant which are adjacent to the semiconductor modules 2 and so become heated to a higher temperature than other parts of the coolant will rise due to buoyancy through the coolant flow passages 31 of the cooling tubes 3, towards the coolant discharge passage 51, and so will exit via the coolant outlet aperture 52, with a flow of liquid coolant at a lower temperature being thereby drawn into the cooled semiconductor unit 1 via the coolant intake aperture 42. Hence, continued natural circulation of the liquid coolant will occur after forced circulation by the circulation pump has been halted, so long as the semiconductor modules 2 remain at a high temperature.

In that way, heat continues to be removed from the semiconductor modules 2 in that condition.

Also as shown in FIGS. 1 to 3, with the coolant supply header 4 and coolant discharge header 5 disposed parallel to one another and the cooling tubes 3 oriented at right angles to the coolant supply header 4 and coolant discharge header 5, the cooled semiconductor unit 1 can readily be made of compact size. Moreover, due to the cooling tubes 3 being oriented vertically, bubbles By which are formed within the coolant flow passages 31 of the cooling tubes 3 are sure to rise upward and so be effectively removed, ensuring that a high efficiency of cooling is maintained.

Furthermore with this embodiment, each of the coolant supply header 4 and coolant discharge header 5 is disposed horizontally with no downward-sloping portions in the coolant supply flow passage 41 or the coolant discharge passage 51. This serves to ensure that vapor bubbles will not remain in the coolant supply flow passage 41 or coolant discharge passage 51, further ensuring that a high efficiency of cooling is maintained.

That is to say, as illustrated in FIGS. 4 and 5, if there were a downwardly-directed portion 62 in the coolant supply flow passage 41 or coolant discharge passage 51, bubbles By of liquid coolant would become trapped in the upper part 620 of the downwardly-directed portion 62. There would be a resultant deterioration of cooling efficiency of those parts of the cooled semiconductor unit 1 that are close to these residual bubbles.

However with the first embodiment as described above, no downwardly-directed (i.e., downward with respect to the flow direction of the coolant) portions are formed in the coolant supply flow passage 41 or the coolant discharge passage 51. Instead, each of these flow passages is oriented horizontally, ensuring that vapor bubbles By will be effectively removed by the flow of liquid coolant Cf.

It can thus be understood that this embodiment provides a cooled semiconductor unit having a high efficiency of cooling.

### Second Embodiment

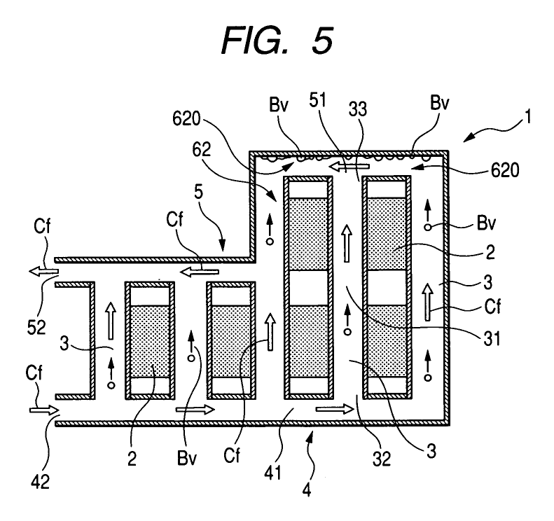

A second embodiment of a cooled semiconductor unit will be described, in which the coolant supply flow passage 41 and coolant discharge passage 51 of a cooled semiconductor unit 100 are formed with respective upwardly (i.e., upward with respect to the flow direction of the coolant Cf) sloping portions 61a, 61b (i.e., such as to produce an upward-sloping direction of flow of the coolant Cf) as shown in the conceptual cross-sectional view of FIG. 6. Alternatively stated, each of the portions 61a of the coolant supply flow passage 41 and portion 61b of the coolant discharge passage 51 is directed upward along the downstream direction of flow of the coolant Cf.

In other respects, the operation and configuration of this embodiment are similar to those of the first embodiment described above, with reference numerals in FIG. 6 designating components that have similar functions to the correspondingly numbered components of the first embodiment.

However with the second embodiment, as a result of providing the upwardly sloping portions 61a, 61b in the coolant supply flow passage 41 and coolant discharge passage 51, it can be more reliably ensured that any bubbles which are present in the liquid coolant Cf, in any part of the interior of the cooled semiconductor unit 1, will be smoothly and completely removed by the flow of the liquid coolant Cf, further ensuring that a high efficiency of cooling is maintained. In other respects, similar effect to those of the first embodiment are obtained.

### Third Embodiment

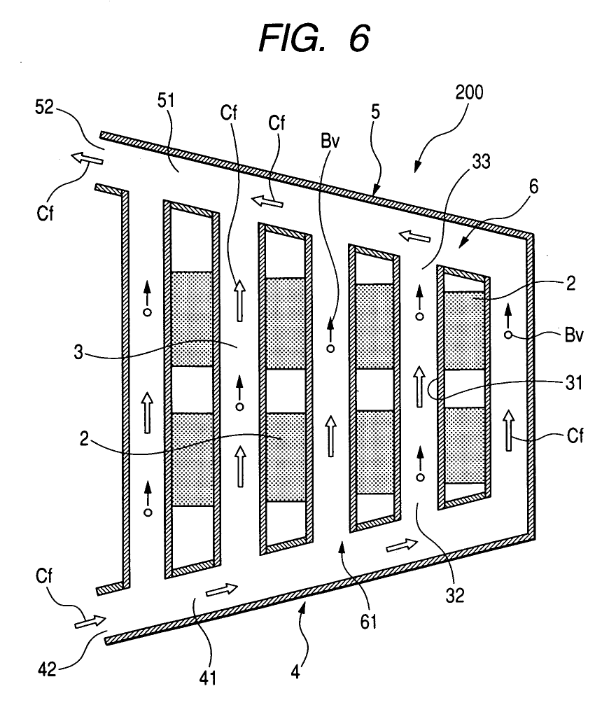

A third embodiment will be described referring to FIG. 7, which is a cross-sectional diagram taken in elevation of a cooled semiconductor unit 200.

With this embodiment, for ease of manufacture, each of the intake end aperture portions 32 has coupling tubes 43 formed thereon, adapted to enable the coupling tubes of adjacent outlet end aperture portions 33 to be joined together. In that way as can be readily understood from FIG. 7, the coolant supply header 4 is constituted by the set of intake end aperture portions 32 and their coupling tubes, in combination. Similarly, each of the outlet end aperture portions 33 has coupling tubes 53 formed thereon, with the coolant discharge header 5 being constituted by the set of intake end aperture portions 32 and their coupling tubes 53, in combination.

A first distinguishing feature of this embodiment is that the cross-sectional area of the flow passage within the coolant discharge header 5 (corresponding to the coolant discharge passage 51 of the preceding embodiments) is made larger than the cross-sectional area of the flow passage within the coolant supply header 4 (corresponding to the coolant supply flow passage 41 of the preceding embodiments). In the same way as described for the preceding embodiments, the intake end aperture portions 32 of the cooling tubes 3 are connected to the coolant supply header 4 (i.e., with each intake end aperture portion 32 opening into the coolant supply flow passage within the coolant supply header 4), and the outlet end aperture portions 33 of the cooling tubes 3 are connected to the coolant discharge header 5 (i.e., with each outlet end aperture portion 33 opening into the coolant discharge passage within the coolant discharge header 5).

The term “cross-sectional area of the flow passage”, as used herein, signifies the cross-section area of a flow passage as taken in a plane at right angles to the direction of flow of the liquid coolant.

A second distinguishing feature of this embodiment is that each of the cooling tubes 3 is provided with cooling fins 7. Each of these cooling fins 7 protrudes into the flow passage within a cooling tube 3, from an inner wall surface of that cooling tube 3, and is oriented along the flow direction, i.e., extends in the vertical direction. In addition, each of the cooling fins 7 is located closely adjacent to a semiconductor module 2, as can be understood from FIG. 7, and hence with this embodiment there are upper and lower sets of cooling fins 7 in each cooling tube 3, respectively corresponding in vertical position to the upper and lower sets of semiconductor modules 2.

A third distinguishing feature of this embodiment is that each of the intake end aperture portions 32 of the cooling tubes 3 is formed with a downwardly extending cavity 44, referred to in the following as a “pocket”, which extends below the flow passage of the coolant supply header 4 (i.e., with each pocket 44 extending downward from the interior of that flow passage). Specifically, with the configuration shown in FIG. 7 in which each intake end aperture portion 32 is formed with coupling tubes 43, the pocket 44 in each intake end aperture portion 32 extends below the coupling tubes 43, so that the pockets 44 constitute the lowermost regions in the coolant supply header 4.

In other respects, the operation and configuration of this embodiment are similar to those of the first embodiment, with reference numerals in FIG. 7 designating components that have similar functions to the correspondingly numbered components of the first embodiment.

The following effects are obtained with this embodiment. Firstly, due to the fact that the cross-sectional area of the flow passage in the coolant discharge header 5 is larger than that of the coolant supply header 4, vapor bubbles that form within the flow paths in the cooling tubes 3 due to boiling of the liquid coolant are more readily extracted by rising into the interior of the coolant discharge header 5. Due to the large volume of the interior of the coolant discharge header 5, the thermal capacity of the liquid coolant contained within the coolant discharge header 5 is large. As a result, the vapor bubbles are readily condensed back into liquid, due to entering the relatively cool liquid within the flow passage of the coolant discharge header 5, so that the bubbles are thereby rapidly dissipated. The efficiency of cooling the semiconductor modules 2 is thereby further enhanced.

Moreover due to the cooling fins 7 being incorporated within the interiors of the cooling tubes 3, the area of contact between the internal surface of each cooling tube 3 and the liquid coolant Cf is increased accordingly, so that the thermal transfer coefficient (i.e., heat exchange efficiency) is increased. The efficiency of cooling the semiconductor modules 2 is thereby further enhanced.

Furthermore as a result of providing the pockets 44 at the lowermost portions of the cooling tubes 3, so that each pocket extends downward to a lower position than the flow passage in the coolant supply header 4, obstruction of the flow of liquid coolant through the cooling tubes 3 due to solid foreign material in the liquid coolant Cf can be prevented. That is to say, if any solid foreign material becomes mixed with the liquid coolant that flows in through the coolant intake aperture 42, then as the liquid coolant rises from the flow passage in the coolant supply header 4 up to the coolant discharge header 5, the solid foreign material will be transported by the liquid coolant Cf into the cooling tubes 3. The solid foreign material will thereby reach the intake end 71 of a set of cooling fins 7 in a cooling tube 3. If the solid foreign material is large enough to clog the intake end 71, it will be held there by the upward flow of the liquid coolant Cf through the cooling tube 3.

Subsequently, when the flow of the liquid coolant Cf is halted, the solid foreign material will fall, under the force of gravity into the lowermost parts of the interior of the coolant supply header 4. If the pockets 44 were not incorporated, then when the flow of liquid coolant Cf is thereafter restarted, the solid foreign material would again be blown upward by the flow of coolant, and so would again reach the intake end 71 of a cooling tube 3. As a result of repetitive occurrences of these events, a substantial amount of solid foreign material would eventually accumulate at the intake ends 71 of the cooling fins 7, thereby reducing the effective cross-sectional area of the flow paths within the cooling tubes 3. The flow rate of the liquid coolant Cf would thereby be reduced, thus deteriorating the cooling efficiency.

However by providing the pockets 44, it can be ensured that each time the flow of liquid coolant Cf is halted, any solid foreign material that has clogged the intake ends 71 of the cooling fins 7 will then drop into the pockets 44, under the force of gravity. Since each of these pockets 44 is located below the main flow path of the liquid coolant Cf within the coolant supply header 4, it can be ensured that the solid foreign material which has fallen into the pockets 44 will remain there when the flow of the liquid coolant Cf is subsequently restarted, without being again lifted by the liquid coolant Cf.

In that way, solid foreign material that enters the interior of the cooled semiconductor unit 200 will be prevented from obstructing the intake ends 71 of the cooling fins 7. The cooling efficiency of the cooled semiconductor unit 200 can thereby be maintained.

In other respects, similar effects to those of the first embodiment are obtained with this embodiment.

With each of the embodiments described above, the cooling tubes 3 are oriented vertically. However it should be noted that the invention is not limited to such a configuration, and it would be equally possible for the cooling tubes 3 to be oriented at a slope with respect to the vertical direction. The essential points are that the outlet end aperture portion 33 of each cooling tube 3 must be higher than the intake end aperture portion 32 of the cooling tube 3, and that the cooling tubes 3 should not contain any downwardly-directed portion, i.e., a portion shaped such as to cause a downward flow of the liquid coolant.

It can thus be understood that the invention is not limited to the described embodiments and that various modifications to these embodiments, or alternative configurations, could be envisaged that fall within the scope of the invention as set out in the appended claims.

What is claimed is:

1. A liquid-cooled semiconductor unit comprising
at least one semiconductor module, with each said semiconductor module enclosing one or more semiconductor elements,
a plurality of cooling tubes arrayed parallel to one another, with each said semiconductor module sandwiched between a corresponding pair of said cooling tubes, and with each of said cooling tubes containing a coolant flow passage for passing a liquid coolant,
a coolant supply header that is connected to respective intake end aperture portions of said cooling tubes, for supplying said liquid coolant to said coolant flow passages, and
a coolant discharge header that is connected to respective outlet end aperture portions of said cooling tubes, for discharging said liquid coolant from said coolant flow passages;
wherein each of said cooling tubes is disposed with said outlet end aperture portion thereof located at a higher elevation than said intake end aperture portion thereof.

2. A liquid-cooled semiconductor unit according to claim 1, wherein said coolant supply header internally comprises a coolant supply flow passage that is oriented horizontally.

3. A liquid-cooled semiconductor unit according to claim 1, wherein said coolant supply header internally comprises a coolant supply flow passage that slopes upward.

4. A liquid-cooled semiconductor unit according to claim 1, wherein said coolant supply header internally comprises a coolant supply flow passage that is formed as a combination of one or more portions that slope upward and one or more portions that are horizontal.

5. A liquid-cooled semiconductor unit according to claim 1, wherein said coolant discharge header internally comprises a coolant discharge passage that is oriented horizontally.

6. A liquid-cooled semiconductor unit according to claim 1, wherein said coolant discharge header internally comprises a coolant discharge passage that slopes upward.

7. A liquid-cooled semiconductor unit according to claim 1, wherein said coolant discharge header internally comprises a coolant discharge passage that is formed as a combination of one or more portions that slope upward and one or more portions that are horizontal.

8. A liquid-cooled semiconductor unit according to claim 1, wherein said coolant supply header and coolant discharge header are disposed parallel to one another and wherein each of said cooling tubes is disposed at right angles to each of said coolant supply header and said coolant discharge header.

9. A liquid-cooled semiconductor unit according to claim 1, wherein each of said cooling tubes is oriented vertically.

10. A liquid-cooled semiconductor unit according to claim 1, wherein said coolant discharge header internally comprises a coolant discharge passage having a cross-sectional area that is larger than a cross-sectional area of a coolant supply flow passage within said coolant supply header.

11. A liquid-cooled semiconductor unit according to claim 1, wherein each of said cooling tubes comprises a plurality of cooling fins disposed within said coolant flow passage of said cooling tube.

12. A liquid-cooled semiconductor unit according to claim 11, comprising a plurality of pockets formed in said coolant supply header, with each of said pockets located directly below a corresponding one of said cooling tubes and with each of said pockets extending downward from within a coolant supply flow passage that is formed internally in said coolant supply header.

13. A liquid-cooled semiconductor unit according to claim 12, wherein said coolant supply header comprises a set of successively joined lower end portions of said plurality of cooling tubes, and wherein each of said pockets is formed in a corresponding one of said lower end portions.

14. A liquid-cooled semiconductor unit comprising one or more semiconductor modules each enclosing one or more semiconductor elements,
a plurality of cooling tubes arrayed parallel to one another, with each of said semiconductor modules sandwiched between a corresponding pair of said cooling tubes, and each of said cooling tubes containing a coolant flow passage for passing a liquid coolant,
a coolant supply header that is connected to respective intake end aperture portions of said cooling tubes, for supplying said liquid coolant to said coolant flow passages, and
a coolant discharge header that is connected to respective outlet end aperture portions of said cooling tubes, for discharging said liquid coolant from said coolant flow passages;
wherein:
each of said cooling tubes is disposed with said outlet end aperture portion thereof located at a higher elevation than said intake end aperture portion thereof;
each of said cooling tubes comprises a plurality of cooling fins disposed within said coolant flow passage of said cooling tube, and
said coolant supply header comprises a plurality of pockets, with each of said pockets located directly below a corresponding one of said cooling tubes and with each of said pockets extending downward from within a coolant supply flow passage that is formed internally in said coolant supply header.

15. A liquid-cooled semiconductor unit according to claim 14, wherein said coolant supply header comprises a set of successively joined lower end portions of said plurality of cooling tubes, and wherein each of said pockets is formed in a corresponding one of said lower end portions.
